(19) United States
(12) Patent Application Publication
(10) Pub. No.: US 2026/0051838 A1
(43) Pub. Date: Feb. 19, 2026

(54) DETERMINING A WINDING TEMPERATURE OF A WINDING OF AN ELECTRIC MOTOR

(71) Applicant: Siemens Aktiengesellschaft, 80333 München (DE)

(72) Inventors: Stefan Drexel, Mörgen (DE); Johann JEMILLER, MitteIneufnach (DE); SVEN LUDWIG KELLNER, Erlangen (DE); KARL-HEINZ KNECHT, Erlangen (DE); STEFAN KÜNZEL, Erlangen (DE); MARKUS LAMPERT, Pfaffenhausen (DE); MIHALY NEMETH-CSOKA, Erlangen (DE); JOHANNES POPP, Erlangen (DE); LARS ROSENBAUM, Kirchhaslach Ot. Greimeltshofen (DE); CARSTEN SPINDLER, Erlangen (DE)

(73) Assignee: Siemens Aktiengesellschaft, 80333 München (DE)

(21) Appl. No.: 19/104,117

(22) PCT Filed: Jun. 13, 2023
(86) PCT No.: PCT/EP2023/065732

§ 371 Date: Feb. 14, 2025

(30) Foreign Application Priority Data
Aug. 18, 2022 (EP) 22191001.1

(51) Int. Cl. H02P 29/64; G01R 27/08; G01R 31/34; H02P 27/08

(52) U.S. Cl. CPC H02P 29/64; G01R 27/08; G01R 31/343; G01R 31/346; H02P 27/08

(57) ABSTRACT

In a method for determining a winding temperature of a winding of an electric motor, a measurement operating state of the electric motor is specified for measuring an electrical winding resistance of the winding, with the measurement operating state being specified by an operating state in which an electric current flowing in the winding is modulated with a modulation frequency. The winding resistance is measured in the measurement operating state of the electric motor, with the winding resistance being calculated from modulations of the electric current and an associated electric voltage that is applied to the winding. The winding temperature is calculated from the measured winding resistance. In an operating state of the electric motor which operating state is different from a measurement operating state, the winding temperature is calculated from an operating parameter of the electric motor using a thermal model.

The invention relates to a method for determining a winding temperature of a winding of an electric motor. Moreover, the invention relates to a current converter which is configured so as to control an electric motor. In general, the electric motor can be a rotating electric machine designed as a synchronous motor or an asynchronous motor, a linear motor or a reluctance motor. Moreover, the term electric motor also includes accordingly-designed generators.

Many electric motors are operated in overload at an inverter. In this case, it is important to protect windings of the electric motors against overheating. In the case of water-cooled or force-ventilated electric motors, overheating can also occur due to cooling failure. In order to provide protection against overheating, a temperature sensor is frequently arranged on the winding of an electric motor and the measured values of the temperature sensor are monitored. The temperature sensor must be safely electrically isolated from the winding. As a result, the thermal connection of the temperature sensor to the winding is not ideal and can lead to a measurement delay of, for example, 10 seconds or more. Moreover, individual winding strands of the winding can be heated to a greater extent than the other winding strands, for example in the case of an overload when the electric motor is at a standstill. If the temperature sensor is not arranged on the most heavily loaded winding strand, the protection implemented with the temperature sensor is insufficient under certain circumstances. Furthermore, the temperature sensor or the supply line of the temperature sensor can fail. A temperature sensor is a sensitive component in an otherwise solid electric motor, and not only is it at risk of failing, but it also does not measure particularly accurately due to delay times and a less than optimal installation position.

DE 10 2014 005 706 A1 discloses a method for operating an electric motor which is activated by an electronic power system. In the case of the method, a motor temperature is determined based on an initial temperature at a start point in time with the aid of a motor temperature model, wherein the initial temperature at the start point in time is calculated with the aid of a predetermined formula from at least one measured motor parameter and the predetermined formula is automatically recalibrated in order to calculate the initial temperature.

US 2021/0305929 A1 discloses a system for controlling a synchronous motor drive that receives a command voltage signal and in the synchronous motor drive identifies a resistance imbalance signature with reference to the command voltage signal. Based on the resistance imbalance signature, the system identifies respective phase resistances which correspond to phases of a synchronous motor of the synchronous motor drive. Based on the phase resistances and an estimated average resistance between the phases of the synchronous motor, one or more phases of the synchronous motor are identified which correspond to one or more phase resistances which represent a resistance imbalance.

Ching-Yin Lee, “Effects of unbalanced voltage on the operation performance of a three-phase induction motor,” in IEEE Transactions on Energy Conversion, Vol. 14, No. 2, pages 202-208, June 1999, doi: 10.1109/60.766984 discloses a real load test in order to examine the effects of an asymmetrical voltage supply on the power of an induction motor.

The object of the invention is to propose an improved method and an improved apparatus for determining a winding temperature of a winding of an electric motor.

The object is achieved in accordance with the invention by a method with the features of claim 1 and a current converter with the features of claim 14.

Advantageous embodiments of the invention are the subject of the subordinate claims.

In the case of a method in accordance with the invention for determining a winding temperature of a winding of an electric motor, at least one measurement operating state of the electric motor is specified for measuring an electrical winding resistance of the winding. In a measurement operating state of the electric motor, the winding resistance is measured and the winding temperature is calculated from the measured winding resistance. In an operating state of the electric motor which is different from a measurement operating state, the winding temperature is calculated from at least one operating parameter of the electric motor using the thermal model.

The invention therefore combines measurements of a winding resistance of the winding of an electric motor using a thermal model for determining a winding temperature of the winding. This makes use of the fact that the winding resistance is temperature-dependent and therefore the winding temperature can be calculated from the winding resistance. However, it is only possible to measure the winding resistance under certain operating conditions of the electric motor. In particular, the motor current must be sufficiently large in order to carry out the measurement so that a sufficiently high voltage drops across the winding resistance. Furthermore, a speed of a rotor of the electric motor, for example, must not be too high in comparison to a stator of the electric motor, in the case of a rotating electrical machine therefore an angular speed of the rotor and, in the case of a linear motor a translational speed of the rotor in order to be able to carry out the measurement. In accordance with the invention, measurement operating states of the electric motor are therefore specified, in which it is possible to measure the winding resistance and a measurement is carried out. In other operating states of the electric motor, in other words in operating states in which it is not possible to measure the winding resistance, in contrast a thermal model is used in order to calculate the winding temperature from at least one operating parameter of the electric motor.

Consequently, the method in accordance with the invention renders it possible to determine the winding temperature without a temperature sensor. As a result, the above mentioned disadvantages of using a temperature sensor are eliminated, namely the risk of the temperature sensor failing and inaccuracies and temporal delays when carrying out the measurements using the temperature sensor. Furthermore, costs relating to the temperature sensor and its installation and cabling are eliminated.

In particular, the invention renders it possible in the measurement operating states to very precisely determine the winding temperature by measuring the winding resistance. This is particularly advantageous, since the measurement operating states are often precisely critical operating states in which individual winding phases are particularly heavily loaded, for example operating states with a negligible or very small speed of the rotor in the case of a high motor current. The values of the winding resistance that are determined in the measurement operating states can furthermore be used advantageously as initial values for the thermal model and/or for updating the thermal model.

In one embodiment of the invention, in the case of a multi-phase electric motor, the temperature of the particular winding strand of the winding of the electric motor which has the highest temperature in the operating state is determined as the winding temperature in an operating state of the electric motor. In this case, the temperature of the particular winding strand which has the highest temperature in the operating state is preferably determined using the thermal model.

The aforementioned embodiment of the invention takes into account that generally it is not possible to measure the phase resistances of the winding strands of the individual phases of a multi-phase electric motor. On the contrary, generally only an averaged resistance which is composed of portions of the individual phase resistances can be measured as a winding resistance, wherein these portions depend upon a prevailing position of a current space vector of the current in the winding. However, with the aid of the thermal model and taking into account the respective position of the current space vector, it is possible with a good degree of accuracy to determine from the averaged resistance the temperature of the particular winding strand of the winding of the electric motor which in the operating state has the highest temperature (see in this respect the exemplary embodiments described below). This temperature is decisive for the protection of the motor. In accordance with the invention, this temperature is therefore determined as the winding temperature of the winding. The calculation of this temperature is preferably implemented in the thermal model so that the thermal model is also especially configured to calculate from the measured winding resistances in each case the temperature of the particular winding strand which has the highest temperature in the respective measurement operating state.

In a further embodiment of the invention, a motor current of the electric motor is used as an operating parameter for the calculation of the winding temperature in an operating state of the electric motor which is different from a measurement operating state. Alternatively or additionally, for example, a speed of a rotor of the electric motor relative to a stator of the electric motor is used as an operating parameter for the calculation of the winding temperature in an operating state of the electric motor which is different from a measurement operating state.

The aforementioned embodiments of the invention take into account that the motor current and the rotor speed of the electric motor are the operating parameters of the electric motor that are essential for the winding temperature.

In a further embodiment of the invention, the winding resistance of the winding of the electric motor is measured by recording at least one electric current flowing in the winding and an electric voltage corresponding thereto and the winding resistance of the winding of the electric motor is calculated from the measured values. In lieu of measuring the voltage, it could be possible in principle to also use a voltage set value of the voltage so as to determine the winding resistance. However, in this case, it is necessary to take into account with sufficient accuracy deviations of the voltage actual value from the voltage set value. Such deviations arise, for example due to the locking times of semiconductor switches used to generate the voltage.

In a further embodiment of the invention, an operating state in which an amount of a current space vector of an electric current flowing in the winding is greater than a predetermined amount threshold value is specified as a measurement operating state of the electric motor. This embodiment of the invention takes into account the criterion already mentioned above for selecting a measurement operating state of the electric motor as an operating state in which the motor current is sufficiently high for performing the measurement so that a sufficiently high voltage drops across the winding resistance.

In a further embodiment of the invention, an operating state in which a rotor of the electric motor does not move or only moves slowly relative to a stator of the electric motor, for example slower than a predetermined speed threshold value, is specified as a measurement operating state of the electric motor. This embodiment of the invention takes into account the criterion already mentioned above for selecting a measurement operating state of the electric motor as an operating state with a negligible or low rotor speed. Additionally, the measurement operating state is specified, for example, by virtue of the fact that at the end of the measuring time period an amount of a current space vector of an electric current flowing in the winding does not significantly differ from the amount at the start of the measuring time period, for example by less than a predetermined deviation threshold value, and the winding resistance is determined as an average value over multiple measurements carried out during the measuring time period, for example over approx. 200 measurements. By determining the winding resistance as an average value over multiple measurements under the mentioned conditions, the measurement error is reduced and the accuracy of the measurement increased.

In accordance with the invention, an operating state during which an electric current flowing in the winding is modulated with a modulation frequency is specified as a measurement operating state, and the winding resistance is calculated from the modulations of the electric current and an associated electric voltage applied at the winding. In the case of a three-phase electric motor, a current along a d-axis and/or a current along a q-axis of a d/q coordinate system is modulated with the modulation frequency, for example.

The aforementioned embodiment of the invention is a measurement method for measuring the winding resistance which can be used alternatively or additionally to the above described measurement method (performing measurements in the case of small rotor speeds under the conditions mentioned above). The winding resistance and the winding temperature are determined from the modulated current and an associated modulated voltage. This measurement method has the advantage that it can also be used when operating the electric motor at higher rotor speeds. However, it does require a modulation of the current in the winding which does not affect the operation of the electric motor and still renders it possible to measure the winding resistance. The thermal model is also preferably used in this measurement method in order to determine from the measured values the temperature of the particular winding strand of the winding which has the highest temperature.

In a further embodiment of the invention, the winding temperature for a winding of a stator of the electric motor is determined.

In a further embodiment of the invention, at least one winding temperature determined in a measurement operating state of the electric motor is used by the thermal model as an initial value when calculating the winding temperature in an operating state which is different from a measurement operating state. This embodiment of the invention takes into account the fact that the thermal model generally calculates the winding temperature iteratively, based on initial values. Since a winding temperature that is determined in a measurement operating state of the electric motor is a measured value or is calculated from measured values, it is suitable as a realistic initial value for the calculation of the winding temperature using the thermal model.

In a further embodiment of the invention, at least one winding temperature determined in a measurement operating state of the electric motor is used by the thermal model when calculating the winding temperature in an operating state which is different from a measurement operating state in order to update the thermal model. This embodiment of the invention renders it possible to update the thermal model, for example by means of a so-called observer, using realistic values of the winding temperature which are determined in measurement operating states and thus improves the accuracy of the thermal model.

A current converter in accordance with the invention is configured so as to control an electric motor and comprises:
a current measuring apparatus which is configured so as to measure at least one electric current in a winding of the electric motor,
a voltage measuring apparatus which is configured so as to measure at least one electric current corresponding to a measured current, and
a computing unit which is configured so as to calculate a winding temperature of the winding of the electric motor from measured values that are recorded in a specified operating state of the electric motor by the current measuring apparatus and the voltage measuring apparatus and in an operating state of the electric motor which is different from a measurement operating state to calculate the winding temperature from at least one operating parameter of the electric motor using the thermal model.

The current converter in accordance with the invention renders it possible to perform the method in accordance with the invention. The advantages of a current converter in accordance with the invention therefore correspond to the above mentioned advantages of the method in accordance with the invention.

The above described characteristics, features and advantages of this invention and the manner in which these are achieved become clearer and more easily understood in conjunction with the following description of exemplary embodiments which are explained in detail in conjunction with the drawings. In the drawing:

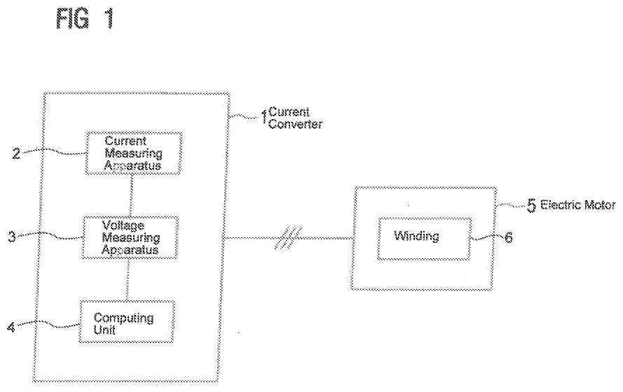

FIG. 1 shows a block diagram of an exemplary embodiment of a current converter for controlling an electric motor,

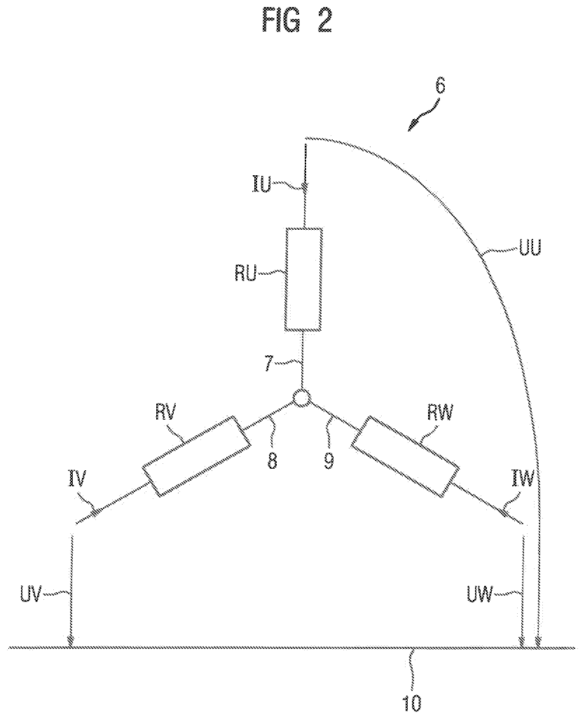

FIG. 2 shows schematically a winding of an electric motor,

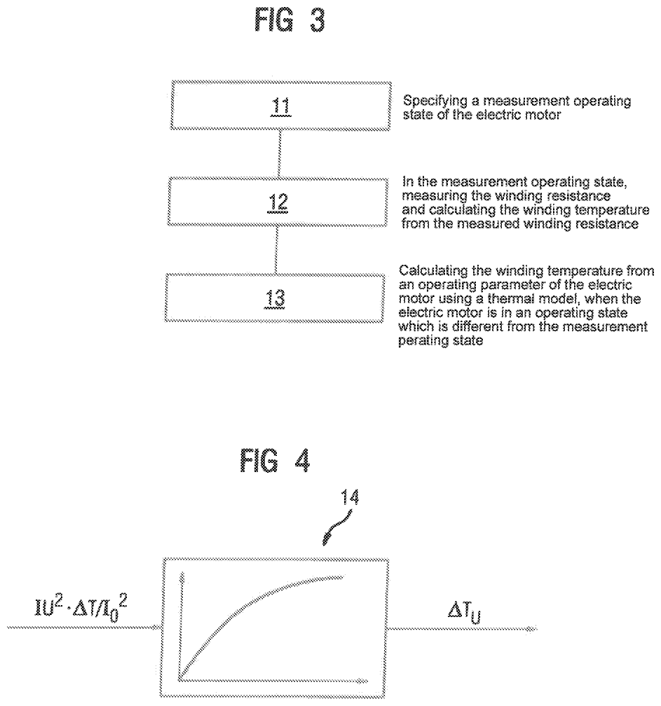

FIG. 3 shows a flow diagram of an exemplary embodiment of the method in accordance with the invention,

FIG. 4 shows a PT1 element for the calculation of a winding temperature of an electric motor.

FIG. 1 (FIG. 1) shows a block diagram of an exemplary embodiment of a current converter 1 for controlling an electric motor 5. In the case of this exemplary embodiment, the electric motor 5 is three-phase with a stator and a rotor. The stator has a winding 6 for which, as described below, winding temperatures are determined in various operating states of the electric motor 5.

FIG. 2 (FIG. 2) shows schematically the winding 6 of the stator of the electric motor 5. The winding 6 has for each phase of the electric motor 5 a winding strand 7, 8, 9. The winding strands 7, 8, 9 are electrically connected to one another in a star connection and are guided in each case by grooves of a laminated core of the stator, for example.

A winding strand 7 of a first phase, referred to as the U phase, has an electrical phase resistance RU. A winding strand 8 of a second phase, referred to as the V phase, has an electrical phase resistance RV. A winding strand 9 of the third phase, referred to as the W phase, has an electrical phase resistance RW. The phase resistances RU, RW, RV are temperature-dependent, i.e. depend upon a temperature of the respective winding strands 7, 8, 9.

During the operation of the electric motor 5, an electrical phase current IU flows in the winding strand 7 of the U phase, an electrical phase current IV flows in the winding strand 8 of the V phase and an electrical phase current IW flows in the winding strand 9 of the W phase.

The current converter 1 has in a known manner for each phase of the electric motor 5, for example, a half bridge (not illustrated here) with two semi-conductor switches which are actuated in a pulse-width-modulated manner. Moreover, the current converter 1 comprises a current measuring apparatus 2 which is configured so as to measure each phase current IU, IV, IW, and a voltage measuring apparatus 3. The voltage measuring apparatus 3 is configured to measure for each winding strand 7, 8, 9 a phase voltage UU, UV, UW between the respective winding strand 7, 8, 9 and an electrical reference line 10 which lies on an electrical reference potential. The reference potential is, for example, a potential of an electrical DC voltage of an electrical intermediate circuit of the current converter 1, from which its semi-conductor switches are supplied with electric voltage.

The current converter 1 also has a computing unit 4 which is configured so as to determine the winding temperature of the winding 6 of the electric motor 5 in accordance with the method described below. The computing unit 4 can be integrated in particular in a control unit of the current converter 1 and the control unit controls the semi-conductor switches of the current converter 1. For example, the computing unit 4 can be realized as a computer program which is implemented in the control unit, can be executed by the control unit and is configured so as to determine the winding temperature of the winding 6 of the electric motor 5.

FIG. 3 (FIG. 3) shows a flow diagram of an exemplary embodiment of the method in accordance with the invention with method steps 11, 12, 13 for determining the winding temperature of the winding 6.

In a first method step 11, at least one measurement operating state of the electric motor 5 is specified for measuring the winding resistance during a measuring time period. For example, an operating state in which during the measuring time period the rotor of the electric motor 5 does not move or only moves slowly relative to the stator of the electric motor 5, for example slower than a predetermined speed threshold value, is specified as a measurement operating state and an amount of a current space vector, which is formed by the phase currents IU, IV, IW, does not significantly differ at the end of the measuring time period from the amount at the start of the measuring time period, for example by less than a predetermined deviation threshold value.

In a second method step 12, in a measurement operating state of the electric motor 5, the winding resistance is measured and the winding temperature is calculated from the measured winding resistance.

In order to measure the winding resistance, the phase currents IU, IV, IW and phase voltages UU, UV, UW, for example are measured multiple times in the measuring time period, for example in each case approx. 200 times, and each phase voltage UU, UV, UW forms an average value. For example the average values of the phase currents IU, IV, IW are used to form a current space vector, which in a rotor fixed d/q coordinate system has an id component along a d-axis and an iq component along a q-axis of the coordinate system. Moreover, a voltage space vector is formed from the average values of the phase voltages UU, UV, UW, which in the d/q coordinate system has a ud component along the d-axis and a uq component along the q-axis. The winding resistance is calculated as a space vector resistance R_{RZS} from the current space vector and the voltage space vector, for example in accordance with:

$${R}_{RZS} = [ ud \cdot iq + ( uq - uL ) \cdot iq ) ] / ( {id}^{2} + {iq}^{2} ) ,$$

wherein UL represents a voltage which is induced by the rotor in the q-direction and is dependent upon a rotor speed of the rotor and is treated, for example, as proportional to the rotor speed.

Using a thermal model of the electric motor 5, the temperature of the particular winding strand 7, 8, 9 which has the highest temperature in the measurement operating state is determined as the winding temperature. For example the winding temperature is calculated from the winding resistance in accordance with:

$$T = {T}_{0} + ( {R}_{RZS} / {R}_{0} - 1 ) \cdot ( 1 / k ) \cdot K$$

with the following designations:
T₀: reference temperature,
R₀: value of the space vector resistance R_{RZS} in the case of the reference temperature,
k: coefficient dependent upon the material of the winding for the temperature dependency of the winding resistance,
K: correction factor.

The correction factor K is used to calculate from the space vector resistance R_{RZS} the temperature of the particular winding strand 7, 8, 9 which has the highest temperature in the measurement operating state as the winding temperature T. For example, the correction factor K is calculated in accordance with:

$$K = ( 3 / 2 ) \cdot {I}^{2} \cdot {max}_{i} \{ PT 1 ( {{I}_{i}}^{2} ) \} / {sum}_{i} \{ PT 1 ( {{I}_{i}}^{2} ) \cdot {{I}_{i}}^{2} \}$$

with the following designations:
I: amount of the current space vector,
i: index which runs over the three phases U, V, W,
PT1 (Iᵢ²): initial value of a PT1 element 14 for the phase i (see FIG. 4 and its description),

$${max}_{i} \{ PT 1 ( {{I}_{i}}^{2} ) \} : maximum of PT 1 ( {IU}^{2} ) , PT 1 ( {IV}^{2} ) and PT 1 ( {IW}^{2} ) ,$$

$${sum}_{i} \{ PT 1 ( {{I}_{i}}^{2} ) \cdot {{I}_{i}}^{2} \} = PT 1 ( {IU}^{2} ) \cdot {IU}^{2} + PT 1 ( {IV}^{2} ) \cdot {IV}^{2} + PT 1 ( {IW}^{2} ) \cdot {IW}^{2} .$$

The correction factor K takes into account that generally the measurements of the phase currents IU, IV, IW and phase voltages UU, UV, UW do not render it possible to determine the phase resistances RU, RV, RW of the winding strands of the individual phases because it is not possible from the measurements of the phase voltages UU, UV, UW, measured in each case with respect to the reference potential of the reference line 10, to determine the voltages of the phase windings 7, 8, 9 with respect to the star point of the star point circuit of the phase windings 7, 8, 9 (see FIG. 2). The average value of the phase voltages UU, UV, UW only produces the star point voltage when all phase resistances RU, RV, RW are equal, which, however, cannot be assumed here due to the different heating of the individual phase windings 7, 8, 9.

FIG. 4 (FIG. 4) shows schematically the PT1 element 14 for the U phase of the winding 6. The initial value for the PT1 element 14 is essentially the square IU² of the phase current IU, multiplied by the ratio ΔT/I₀², wherein ΔT represents a temperature increase ΔT of the winding strand 7 of the U phase in the case of a reference current I₀, for example at a standstill current of the electric motor 5. The initial value PT1(IU²)=ΔTᵤ of the PT1 element 14 is a temperature increase ΔTᵤ of the winding strand 7 of the U phase in dependence upon the initial value with respect to the reference temperature. The PT1 elements for the phases V and W correspond to the PT1 element for the U phase, wherein the initial values of these PT1 elements contain the squares IV² or IW² in lieu of IU².

The determination of the winding temperature as described in FIGS. 2 and 3 can be modified in various ways, in particular, it can be refined. For example, the calculation of the winding temperature can take into account the influence of a laminated core of the stator and/or of the rotor of the electric motor 5.

In a third method step 13, in an operating state of the electric motor 5 which is different from a measurement operating state, the winding temperature is calculated from at least one operating parameter of the electric motor 5 using the thermal model. In so doing, a motor current of the electric motor 5 is used, for example, as an operating parameter for the calculation of the winding temperature. Alternatively or additionally, the speed of the rotor of the electric motor 5 relative to the stator of the electric motor 5, for example, is used as an operating parameter for the calculation of the winding temperature. For example, a winding temperature determined in a measurement operating state of the electric motor 5 is used as an initial value when calculating the winding temperature. Moreover, winding temperatures which are determined in each case in a measurement operating state of the electric motor 5 can be used to update the thermal model.

Although the invention has been further illustrated and described in detail by preferred exemplary embodiments, the invention is not limited by the disclosed examples and other variations can be derived therefrom by the person skilled in the art without departing from the scope of protection of the invention.

1.-14. (canceled)

15. A method for determining a winding temperature of a winding of an electric motor, the method comprising:
specifying a measurement operating state of the electric motor for measuring an electrical winding resistance of the winding;
calculating the winding resistance in the measurement operating state of the electric motor from a modulation of an electric current flowing in the winding with a modulation frequency and an electric voltage applied at the winding;
calculating the winding temperature from the measured winding resistance; and
calculating the winding temperature in an operating state of the electric motor from an operating parameter of the electric motor using a thermal model which operating state is different from a measurement operating state.

16. The method of claim 15, wherein the electric motor is a multi-phase electric motor, and wherein the winding temperature in an operating state of the electric motor is determined as a temperature of a winding strand of the winding which temperature is highest in the operating state.

17. The method of claim 16, further comprising determining the temperature of the winding strand having the highest temperature in the operating state using the thermal model.

18. The method of claim 15, further comprising using a motor current of the electric motor as the operating parameter for calculating the winding temperature in the operating state of the electric motor which operating state is different from the measurement operating state.

19. The method of claim 15, further comprising using a speed of a rotor of the electric motor relative to a stator of the electric motor as the operating parameter for calculating the winding temperature in the operating state of the electric motor which operating state is different from a measurement operating state.

20. The method of claim 15, wherein the winding resistance of the winding of the electric motor is measured by recording an electric current flowing in the winding and an electric voltage corresponding to the electric current and to generate therefrom measured values, and the winding resistance of the winding of the electric motor is calculated from the measured values.

21. The method of claim 15, further comprising specifying the operating state as the measurement operating state of the electric motor by an absolute value of a current space vector of an electric current flowing in the winding is greater than a predetermined absolute threshold value.

22. The method of claim 15, further comprising specifying the operating state as the measurement operating state of the electric motor, when a rotor of the electric motor does not move or only moves slowly relative to a stator of the electric motor.

23. The method of claim 22, wherein the rotor of the electric motor moves slower than a predetermined speed threshold value.

24. The method of claim 15, further comprising:
additionally specifying the measurement operating state when at an end of a measuring time period a magnitude of a current space vector of an electric current flowing in the winding does not significantly differ from a magnitude at a start of the measuring time period; and
determining the winding resistance as an average value over multiple measurements carried out during the measuring time period.

25. The method of claim 24, wherein the magnitude of a current space vector at the end of a measuring time period differs from the magnitude at a start of the measuring time period by less than a predetermined deviation threshold value.

26. The method of claim 15, wherein the electric motor is a three-phase electric motor, the method further comprising modulating a current along a d-axis and/or a current along a q-axis of a d/q coordinate system with the modulation frequency.

27. The method of claim 15, wherein the winding temperature is determined for a winding of a stator of the electric motor.

28. The method of claim 15, further comprising using a winding temperature determined in the measurement operating state of the electric motor by the thermal model as an initial value when calculating the winding temperature in the operating state which is different from the measurement operating state.

29. The method of claim 15, wherein when calculating the winding temperature in the operating state that is different from the measurement operating state, updating the thermal model using a winding temperature determined in the measurement operating state of the electric motor.

30. A current converter for controlling an electric motor, the current converter comprising:
a current measuring apparatus designed to measure an electric current in a winding of the electric motor;
a voltage measuring apparatus designed to measure an electric voltage corresponding to the measured current;
a computing unit designed to calculate in a specified measurement operating state of the electric motor a winding temperature of the winding of the electric motor from measured values that are recorded by the current measuring apparatus and the voltage measuring apparatus and to calculate in an operating state of the electric motor which operating state is different from the measurement operating state the winding temperature from an operating parameter of the electric motor using a thermal model,
wherein the measurement operating state is specified as an operating state during which an electric current flowing in the winding is modulated with a modulation frequency, and
wherein the winding resistance is calculated from modulations of the electric current and an associated electric voltage applied at the winding.
